(19) United States
(12) Patent Application Publication
(10) Pub. No.: US 2004/0087106 A1
(43) Pub. Date: May 6, 2004

(54) Method for forming isolation film in silicon substrate

(76) Inventor: Bong Cheon Kim, Chungcheongbuk-do (KR)

Correspondence Address: LADAS & PARRY, 224 SOUTH MICHIGAN AVENUE, SUITE 1200, CHICAGO, IL, 60604, US

(21) Appl. No.: 10/616,817

(22) Filed: Jul. 10, 2003

(30) Foreign Application Priority Data
Oct. 31, 2002 (KR) 2002-67024

(51) Int. Cl. H01L 21/76

(52) U.S. Cl. 438/424

(57) ABSTRACT

Disclosed herein is a method for forming an isolation film in a silicon substrate, using a shallow trench isolation (STI) process. This method comprises the steps of: successively depositing a pad oxide film, a pad nitride film and a poly-silicon film on a silicon substrate; patterning the deposited films to expose a portion of the substrate, which correspond to a field region; etching the exposed portion of the substrate to form a trench; depositing an HDP-oxide film on the substrate to the same thickness as the sum of the thickness of the deposited films and the depth of the trench in such a manner as to fill the trench; forming a reverse mask on the HDP-oxide film, which covers the field region and a portion of an active region extending inward from the edge of the active region by a given distance; etching an exposed portion of the HDP-oxide film formed on the active region using the reverse mask as an etch barrier; removing the reverse mask; subjecting the HDP-oxide film and the poly-silicon film to chemical mechanical polishing (CMP); and removing the pad nitride film. According to the present invention, before subjecting the HDP-oxide film to the CMP step, the step height of the HDP-oxide is removed to improve CMP uniformity. Also, since an oxide etchant is not used in the removal of the pad nitride film, the formation of a moat can be basically inhibited.

### BACKGROUND OF THE INVENTION

1. Field of the Invention

The present invention relates to a method for forming an isolation film in a silicon substrate using a shallow trench isolation (STI) process. More particularly, the present invention relates to a method for forming an isolation film in a silicon substrate, which can improve the chemical mechanical polishing (CMP) uniformity of a trench-filling oxide film, and at the same time, inhibit the formation of a moat.

2. Description of the Prior Art

As well known in the art, in recent semiconductor devices, an isolation film providing electrical insulation between devices is formed using a shallow trench isolation (STI) process. In the conventional LOCOS process, a bird's beak is formed at the upper edge of the isolation film such that the size of an active region is reduced. On the other hand, in the STI process, the isolation film can be formed in narrow width such that the size of the active region can be ensured. For this reason, the STI process is used as substitute for the LOCOS process.

Hereinafter, the conventional method for forming an isolation film using the STI process will be described in brief.

First, a pad oxide film and a pad nitride film are successively formed on a silicon substrate, and patterned to expose a portion of the substrate, which corresponds to a field region.

Then, the exposed portion of the substrate is etched to form a trench, after which the resulting substrate is subjected to a sacrificial oxidation process, followed by a linear oxidation processes.

Next, a high-density plasma (HDP)-oxide film having excellent filling characteristics is deposited on the entire surface of the substrate, and then, subjected to chemical mechanical polishing (CMP) until the pad nitride film is exposed.

Thereafter, the pad nitride film, which was used as an etch barrier upon the trench etching, is removed, thereby completing the formation of the isolation film.

However, the conventional STI process has the following problems.

First, an HDP-oxide film filling a trench is generally deposited according to the profile of a base layer. As shown in FIG. 1, an HDP-oxide film 4 deposited on an active region of a substrate has a triangle or trapezoid shape depending on the size of the active region, and this non-uniform deposition profile results in a reduction in uniformity of the subsequent CMP process and finally causes a reduction in device characteristics. In FIG. 1, the reference numerals 1, 2 and 3 designate a silicon substrate, a pad oxide film and a pad nitride film, respectively.

In an attempt to improve the CMP uniformity, there was recently proposed a technology wherein a given amount of the HDP-oxide film formed on the active region larger than a given size is removed by a reverse mask-forming process and a reverse etching process. However, the reverse mask forming and etching processes cause an increase in step height, and also can still not remove step heights formed on both sides of the active region, and thus, serve as a source of particles in the subsequent CMP process.

Second, after the HDP-oxide film present on the active region is removed, the thickness of the isolation film varies depending on the pad nitride film used as a polishing stopper layer. In the conventional STI process, the thickness variation between pad nitride films remaining on a wide active region and on a narrow active region is excessive, and also the dishing variation between isolation films formed on a wide field region and on a narrow field region is excessive.

Third, in the conventional STI process, before the pad nitride film is removed, a substrate is dipped in an oxide etchant for several seconds in order to remove oxides, which would be produced on the surface of the pad nitride film. Then, the pad nitride film is removed by a phosphoric acid solution. In this case, the corrosion of the oxide film at the boundary between the active region and the field region occurs to form a moat, thereby deteriorating device characteristics.

### SUMMARY OF THE INVENTION

Accordingly, the present invention has been made to solve the above-mentioned problems occurring in the prior art, and an object of the present invention is to provide a method for forming an isolation film in a silicon substrate, which can improve CMP uniformity, reduce dishing variation and inhibit the formation of a moat.

To achieve the above object, the present invention provides a method for forming an isolation film in a silicon substrate, which comprises the steps of: successively depositing a pad oxide film, a pad nitride film and a poly-silicon film on a silicon substrate; patterning the poly-silicon film, the pad nitride film and the pad oxide film to expose a portion of the substrate, which correspond to a field region of the substrate; etching the exposed portion of the substrate to form a trench; depositing an HDP-oxide film on the resulting substrate to the same thickness as the sum of the thickness of the deposited films and the depth of the trench in such a manner as to fill the trench; forming a reverse mask on the HDP-oxide film, which covers the field region and a portion of an active region, which is adjacent to the field region and extends inward from the edge of the active region by a given distance; etching an exposed portion of the HDP-oxide film formed on the active region using the reverse mask as an etch barrier; removing the reverse mask; subjecting the HDP-oxide film and the poly-silicon film to chemical mechanical polishing (CMP); and removing the pad nitride film.

In the method of the present invention, the reverse mask is preferably formed in such a manner as to cover the field region and a portion of the active region which is adjacent to the field region and extends inward from the edge of the active region by a distance of 0.04-0.05 μm.

Moreover, the step of etching a portion of the HDP-oxide film formed on the active region is preferably carried out using at least one gas selected from the group consisting of CₓF_{y}, O₂, Ar and CHₓF_{y}. Furthermore, the step of etching a portion of the HDP-oxide film formed on the active region is preferably carried out using the poly-silicon film as an etch stopper, at an etch selectivity of the oxide film to the poly-silicon film greater than 100:1.

Also, the step of subjecting the HDP-oxide film and the poly-silicon film to CMP is preferably carried out in such a manner that the surface of the pad nitride film is removed to a thickness of about 100-200 Å after the poly-silicon film was completely removed.

In addition, the step of removing the pad nitride film is preferably carried out using a mixed solution of nitric acid (HNO₃) and phosphoric acid (H₃PO₄).

According to the present invention, the step height of the HDP-oxide film is removed before the HDP-oxide film is subjected to CMP. This can improve CMP uniformity. In addition, upon the removal of the pad nitride film, an oxide etchant is not used, so that the formation of a moat can be basically inhibited.

### BRIEF DESCRIPTION OF THE DRAWINGS

The above and other objects, features and advantages of the present invention will be more apparent from the following detailed description taken in conjunction with the accompanying drawings, in which:

FIG. 1 is a cross-sectional view for illustrating problems occurring in the conventional method for forming an isolation film in a silicon substrate using a shallow trench isolation (STI) process; and

FIGS. 2a to 2e are cross-sectional views illustrating a method for forming an isolation film in a silicon substrate according to a preferred embodiment of the present invention.

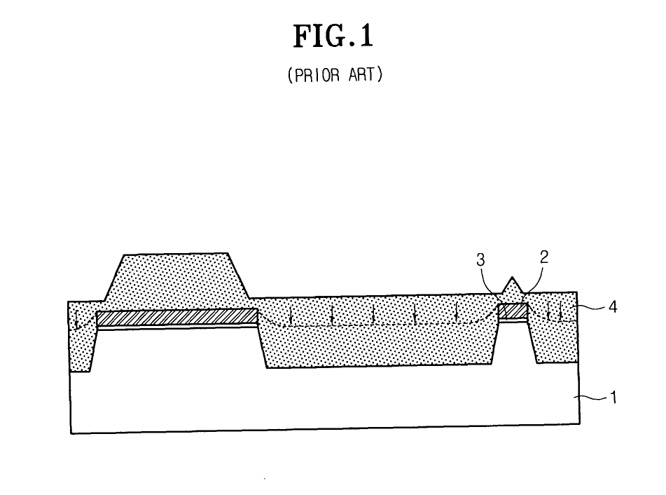

### DETAILED DESCRIPTION OF THE PREFERRED EMBODIMENTS

Hereinafter, a preferred embodiment of the present invention will be described in detail with reference to the accompanying drawings.

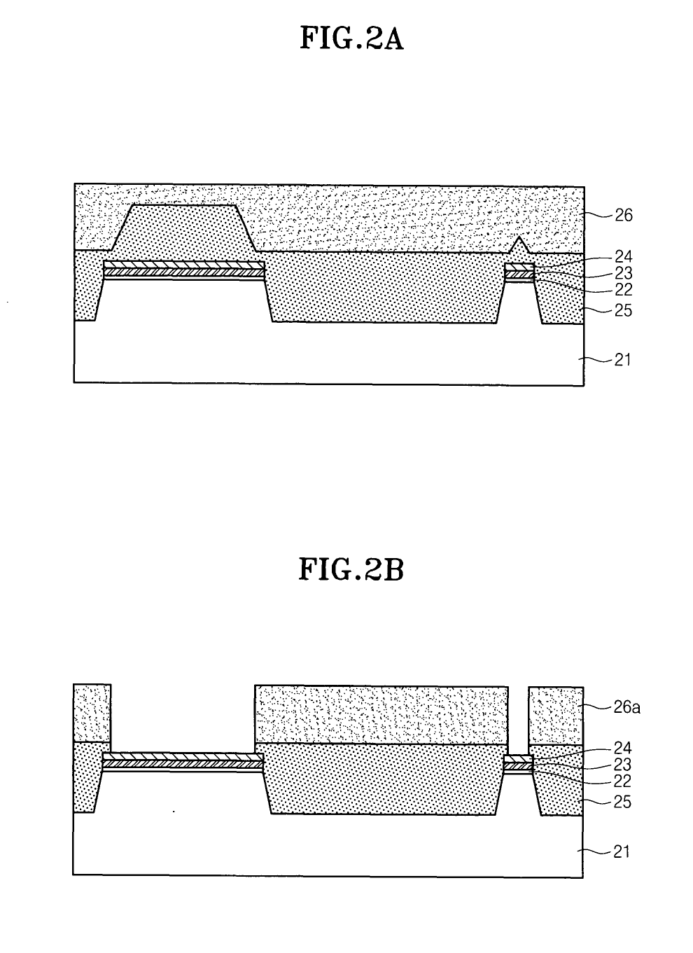

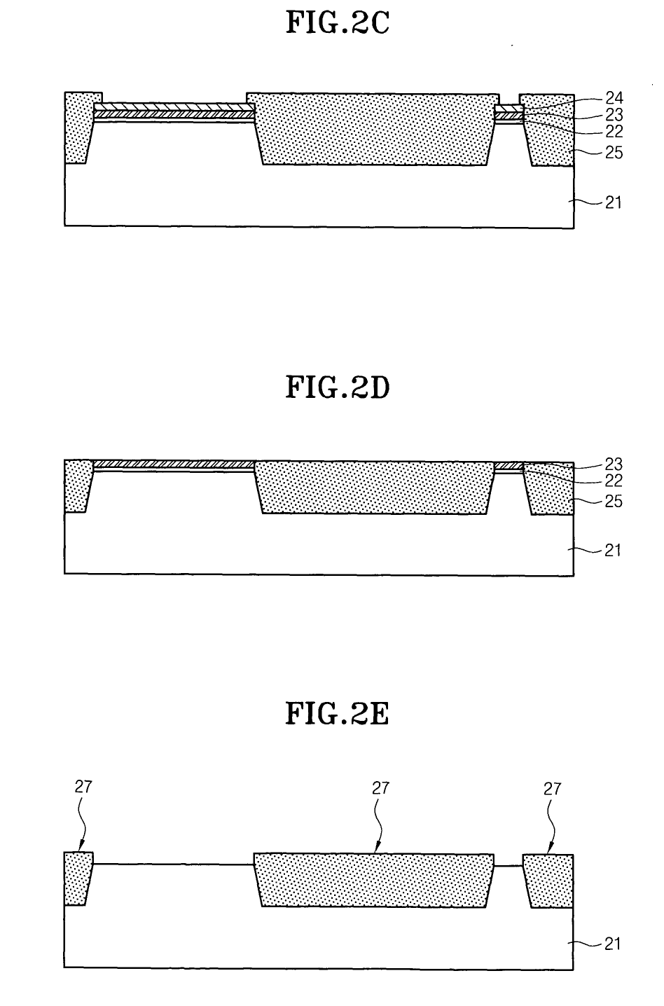

FIGS. 2a to 2e are cross-sectional views illustrating a method for forming an isolation film in a silicon substrate according to a preferred embodiment of the present invention.

Referring to FIG. 2a, a pad oxide film 22 and a pad nitride film 23 are successively formed on a silicon substrate 21 to a thickness of 50-200 Å and a thickness of 500-2,000 Å, respectively. On the pad nitride film 23, a poly-silicon film 24 to be used as an etch stopper in the subsequent process is deposited to a thickness of 100-1,000 Å.

Then, the poly-silicon film 24, the pad nitride film 23 and the pad oxide film 22 are patterned to expose a portion of the substrate, which corresponds to a field region. Then, the exposed portion of the substrate is etched to a given depth to form a trench, after which an HDP-oxide film 25 is deposited on the resulting substrate in such a manner as to fill the trench. In this case, the HDP-oxide film 25 is deposited to the same thickness as the sum of the thickness of the deposited films 22, 23 and 24 and the depth of the trench. Subsequently, a photoresist 26 for forming a reverse mask is applied on the HDP-oxide film 25.

Referring to FIG. 2b, the photoresist 26 is exposed to light and developed to form a reverse mask 26a. In this case, the reverse mask 26a is formed in such a manner as to cover the field region and a portion of an active region, which is adjacent to the field region and extends inward from the edge of the active region by a given distance, for example, 0.04-0.05 μm.

Then, the HDP-oxide film is subjected to reverse etching to remove a portion of the HDP-oxide film formed on the active region. In this reverse etching, the poly-silicon film 24 is used as an etch stopper layer, at least one gas selected from the group consisting of CₓF_{y}, O₂, Ar and CHₓF_{y} is used as reaction gas, and the etch selectivity of the oxide film to the poly-silicon film is greater than 100:1.

Referring to FIG. 2c, the remaining reverse mask is removed according to the conventional process. As a result of the removal of the reverse mask, it can be found that a difference in step height between the active region and the field region is significantly reduced as compared to the prior art.

Referring to FIG. 2d, the resulting substrate is subjected to CMP, thereby forming a trench isolation film 27 in the field region of the substrate. In this CMP, the pad oxide film 23 is overly polished such that the poly-silicon film, which was used as the etch stopper layer in the reverse etching, is completely removed. In other words, by the use of selective or non-selective slurry, after the poly-silicon film is completely removed, the surface of the pad nitride film is removed to a thickness of 100-200 Å.

Referring to FIG. 2e, the remaining pad nitride film is removed by a mixed solution of nitric acid (HNO₃) as a poly-etchant and phosphoric acid (H₃PO₄) as a nitride etchant. In this way, the formation of the isolation film 27 is completed.

As described above, according to the method of the present invention, the reduction of CMP uniformity caused by the step height of the HDP-oxide film is inhibited. Furthermore, the dishing variation between a wide field region and a narrow field region can be reduced and also the formation of a moat at the boundary between the active region and the field region can be prevented.

Generally, the deposition profile of the HDP-oxide film has a trapezoid shape on an active region larger than a given size, and a triangle shape on an active region smaller than a given size. These shapes are generally divided with respect to an active region size of 0.7 μm, although this standard may vary depending on the depth and slope of a trench. A characteristic, which is shown after the deposition of the HDP-oxide film, is that the stop height of the HDP-oxide film starts from a location extended inward from the edge of the active region to about 0.04 μm.

For this reason, the interval between the start point and endpoint of stop height of the HDP-oxide film deposited on the wide active region is narrower than the size of the active region. Thus, if the reverse mask and the etch barrier layer to be used in an etchback process are provided at a lower portion of the HDP-oxide film, all step heights produced upon the deposition of the HDP-oxide film can be removed.

Therefore, according to the method of the present invention, the size of the HDP-oxide film formed on the active region, which will be removed in the reverse mask and etchback processes, is set to RA-0.1 μm in which RA is the actual size of an active region, including the size of an N-active region and the size of a P-active region. This allows the removal of all step heights produced upon the deposition of the HDP-oxide film. As a result, CMP uniformity can be improved and the dishing variation between the isolation regions can be maximally inhibited.

In addition, in the method of the present invention, since the mixed solution of nitric acid (HN0₃) and phosphoric acid (H₃PO₄) is used to remove the pad nitride film, the formation of a moat caused by the use of an oxide etchant upon the removal of the pad nitride film can be prevented.

As described above, according to the present invention, the step height of the HDP-oxide film is removed before the HDP-oxide film is subjected to the CMP process. Thus, dishing in a relatively wide field region can be minimized due to a reduced polishing amount. In addition, CMP uniformity can be improved, and accordingly, device characteristics can be improved.

Furthermore, in the present invention, an oxide etchant is not used in the removal of the pad nitride film so that the formation of a moat is basically inhibited. Thus, the reduction of device characteristics, such as the formation of a hump, can be prevented.

Although a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A method for forming an isolation film in a silicon substrate, which comprises the steps of:
successively depositing a pad oxide film, a pad nitride film and a poly-silicon film on a silicon substrate;
patterning the poly-silicon film, the pad nitride film and the pad oxide film to expose a portion of the substrate, which correspond to a field region of the substrate;
etching the exposed portion of the substrate to form a trench;
depositing an HDP-oxide film on the resulting substrate to the same thickness as the sum of the thickness of the deposited films and the depth of the trench in such a manner as to fill the trench;
forming a reverse mask on the HDP-oxide film, which covers the field region and a portion of an active region, which is adjacent to the field region and extends inward from the edge of the active region by a given distance;
etching an exposed portion of the HDP-oxide film formed on the active region using the reverse mask as an etch barrier;
removing the reverse mask;
subjecting the HDP-oxide film and the poly-silicon film to chemical mechanical polishing (CMP); and
removing the pad nitride film.

2. The method of claim 1, wherein the reverse mask is formed in such a manner as to cover the field region and a portion of the active region which is adjacent to the field region and extends inward from the edge of the active region by a distance of 0.04-0.05 μm.

3. The method of claim 1, wherein the step of etching a portion of the HDP-oxide film formed on the active region is carried out using at least one gas selected from the group consisting of CₓF_{y}, O₂, Ar and CHₓF_{y}.

4. The method of claim 1, wherein the step of etching a portion of the HDP-oxide film formed on the active region is carried out using the poly-silicon film as an etch stopper, at an etch selectivity of the oxide film to the poly-silicon film greater than 100:1.

5. The method of claim 1, wherein the step of subjecting the HDP-oxide film and the poly-silicon film to CMP is carried out in such a manner that the surface of the pad nitride film is removed to a thickness of about 100-200 Å after the poly-silicon film was completely removed.

6. The method of claim 1, wherein the step of removing the pad nitride film is carried out using a mixed solution of nitric acid (HNO₃) and phosphoric acid (H₃PO₄).
